(19) United States
(12) Patent Application Publication
(10) Pub. No.: US 2024/0427235 A1
(43) Pub. Date: Dec. 26, 2024

(54) NANOPATTERNED SUBSTRATES

(71) Applicant: CORNING INCORPORATED, CORNING, NY (US)

(72) Inventors: Robert Alan Bellman, Ithaca, NY (US); Leonard Charles Dabich, II, Painted Post, NY (US); Barry James Paddock, Horseheads, NY (US); Mark Alejandro Quesada, Horseheads, NY (US); Bin Zhu, Ithaca, NY (US)

(21) Appl. No.: 18/746,402

(22) Filed: Jun. 18, 2024

Related U.S. Application Data
(60) Provisional application No. 63/522,463, filed on Jun. 22, 2023.

(51) Int. Cl. G03F 7/00; G03F 7/20; G03F 7/40

(52) U.S. Cl. CPC G03F 7/0002; G03F 7/2004; G03F 7/40

(57) ABSTRACT

A method of forming a nanopatterned substrate includes imprinting a deposited photoresist on a substrate with a stamp to form a nanopattern including nanofeatures on the substrate, the nanofeatures including a gap therebetween. The method includes performing glancing angle deposition of a metal on the nanopattern to deposit the metal on the nanofeatures. The method includes directionally etching the nanopattern including the metal in a direction normal to a surface of the nanopattern to remove the photoresist in the gap between the nanofeatures and to expose the substrate in the gap between the nanofeatures. The method includes depositing a deposition material on the directionally etched nanopattern such that the deposition material is deposited on the exposed substrate in the gap between the nanofeatures and on the metal that is on the nanofeatures. The method also includes dissolving the deposited photoresist including the deposited deposition material thereon to remove the photoresist, the metal, and portions of the deposited deposition material that are on the photoresist from the substrate, to form the nanopatterned substrate including the deposition material deposited on the substrate in the gap between the nanofeatures.

### CROSS-REFERENCE TO RELATED APPLICATIONS

This application claims the benefit of priority under 35 U.S.C. § 119 of U.S. Provisional Application Ser. No. 63/522,463 filed on Jun. 22, 2023, the content of which is relied upon and incorporated herein by reference in its entirety.

### BACKGROUND

Fabricating nano-surface topologies on material substrates in a scalable, low-cost fashion deeply impacts the emerging commercial world of modern metasurface optics, due to their ultra-flat nature and compact optics packed with significant optical function. While various technologies have been brought to bear to scale fabrication of these sub-micron patterned optics, nanoimprint technology in the form of nanoimprint lithography (NIL) (see, FIG. 1) is generally recognized as a significant addition to the technology of scaling nanofeature fabrication at higher throughput and lower cost. Yet, numerous factors limit NIL photoresist generation of high-resolution reproducible nanostructures towards the lower end of the nano range (˜20-150 nm). These include the reactive ion etching (RIE) step (see, Step 5 in FIG. 1) that expose the lower depths of the nanoimprint pattern for subsequent deposition steps (see, Step 6 in FIG. 1) of optical material with specified refractive index, which can severely detract from the resolution inherent from the nanoimprinting.

### SUMMARY OF THE INVENTION

In various aspects, the present invention provides a method of forming a nanopatterned substrate. The method includes imprinting a deposited photoresist on a substrate with a stamp to form a nanopattern including nanofeatures on the substrate, the nanofeatures including a gap therebetween. The method includes performing glancing angle deposition of a metal on the nanopattern to deposit the metal on the nanofeatures. The method includes directionally etching the nanopattern including the metal in a direction normal to a surface of the nanopattern to remove the photoresist in the gap between the nanofeatures and to expose the substrate in the gap between the nanofeatures. The method includes depositing a deposition material on the directionally etched nanopattern such that the deposition material is deposited on the exposed substrate in the gap between the nanofeatures and on the metal that is on the nanofeatures. The method also includes dissolving the deposited photoresist including the deposited deposition material thereon to remove the photoresist, the metal, and portions of the deposited deposition material that are on the photoresist from the substrate, to form the nanopatterned substrate including the deposition material deposited on the substrate in the gap between the nanofeatures.

In various aspects, the present invention provides a method of making a linear wire-grid polarizer. The method includes imprinting a deposited photoresist on a substrate with a stamp to form a nanopattern including nanofeatures on the substrate, the nanofeatures including a gap therebetween. The method includes performing glancing angle deposition of a metal including Al on the nanopattern to deposit the metal on the nanofeatures. The method includes directionally etching the nanopattern including the metal in a direction normal to a surface of the nanopattern to remove the photoresist in the gap between the nanofeatures and to expose the substrate in the gap between the nanofeatures. The method includes depositing a deposition material including Al on the directionally etched nanopattern such that the deposition material is deposited on the exposed substrate in the gap between the nanofeatures and on the metal that is on the nanofeatures. The method also includes dissolving the deposited photoresist including the deposited deposition material thereon to remove the photoresist, the metal, and portions of the deposited deposition material that are on the photoresist from the substrate, to form the linear wire-grid polarizer including the deposition material deposited on the substrate in the gap between the nanofeatures. The deposition material that is deposited on the substrate in the gap between the nanofeatures has a pitch of 160 nm to 180 nm and a width of 80 nm to 90 nm.

In various aspects, the present invention provides a capped nanopatterned substrate including a substrate and a nanopattern including nanofeatures that include nanopores, nanopillars, nanowires, or a combination thereof. The nanofeatures contact the substrate and include a deposited metal. The capped nanopatterned substrate also includes one or more caps on the nanofeatures, wherein the caps are free of contact with the substrate, wherein the caps include a deposited second metal.

In various aspects of the present invention, the glancing angle metal deposition provides masking of 3-dimensional features fabricated from the relatively crude nanoimprint technique shown in FIG. 1. We found that metal adatom structures are highly resistant to the oxidation step of the classic recipes used for organic material removal and are therefore suitable as a masking material for “dry” etching. Higher aspect ratio nanostructures can be produced by various aspects of the method of the present invention including by laying down thicker resist structures (e.g., via spin or spray-coating) and exposing the metal-capped promontories (see, e.g., FIG. 3). In various aspects of the present invention, the method can provide higher resolution nanosurface topologies, cleaner and easier lift-off, provide walls that are more vertical, can provide higher aspect ratios, can provide lower cost manufacturing of nanopatterned nanosurfaces, and/or can provide more efficient scalability for larger area fabrication, such as compared to other nanoimprint methods that do not include glancing angle metal deposition. In various aspects of the present invention, the method can provide a nanopatterned substrate with variable channel widths. In various aspects of the present invention, the method can be used to form a wire-grid polarizer having a high extinction coefficient (transmission ratio of perpendicular to parallel terms), which can be prepared at low cost and high throughput, and which, for example, can be useful for forming an LCD display with a high contrast ratio. In various aspects of the present invention, the method can include a second glancing angle deposition step to form a capped nanopatterned substrate which can include rim-like caps on the nanofeatures thereof, which can provide access to new nanoarchitectures and/or can provide new routes to biomimetic nanooptics.

### BRIEF DESCRIPTION OF THE FIGURES

The drawings illustrate generally, by way of example, but not by way of limitation, various aspects of the present invention.

FIG. 1 illustrates a schematic illustrating a nanoimprint lithography (NIL) method.

FIG. 2 illustrates a schematic illustrating a nanoimprint after step 5 of FIG. 1 (top), with film deposition (middle) and lift-off (bottom).

FIG. 3 illustrates a top view of a dewetted sample (left top), a SEM image of the dewetted sample illustrating the surface including randomly distributed circular nano-trapezoids (left bottom), a schematic illustrating glancing angle deposition (GLAD) (middle), and a SEM image illustrating the product of GLAD including caps (right), in accordance with various aspects.

FIG. 4 illustrates a sequence of steps including (A) providing an NIL nanofeature surface resulting from step 4 of FIG. 1, (B) GLAD, (C) directional dry etching, and (D) deposition and dissolution, in accordance with various aspects.

FIG. 5A illustrates a schematic showing a product of GLAD including caps (top), a product of film deposition thereon (middle), and a product formed after lift-off, in accordance with various aspects.

FIG. 5B illustrates a schematic illustrating a nanoimprint after step 5 of FIG. 1 (top), with film deposition (middle) and lift-off (bottom).

FIG. 6 illustrates a grating daughter formed after step 4 of FIG. 1, including dimensions (top left), side illustration (middle left), photograph from top (bottom left), and a SEM image thereof (right).

FIG. 7A illustrates a photograph of a GLAD apparatus, in accordance with various aspects.

FIG. 7B illustrates a photograph of the chamber of the GLAD apparatus from FIG. 7A, which contains the GLAD fixture, in accordance with various aspects.

FIG. 7C illustrates a photograph showing a top-view of the GLAD apparatus shown in FIG. 7A.

FIG. 8A illustrates a SEM image of sample 1 after GLAD deposition with ˜75 nm Al, in accordance with various aspects.

FIG. 8B illustrates a SEM image of sample 1 after GLAD deposition with a line indicating the source of EDX scan data in FIG. 8C, in accordance with various aspects.

FIG. 8C illustrates an EDX scan of sample 1 corresponding to the portion of sample 1 shown in FIG. 8B, in accordance with various aspects.

FIGS. 8D-8E illustrate SEM images of sample 2 after GLAD deposition with ˜150 nm Al, in accordance with various aspects.

FIG. 8F illustrates a SEM image of sample 2 after GLAD deposition with a line indicating the source of EDX scan data in FIG. 8G, in accordance with various aspects.

FIG. 8G illustrates an EDX scan of sample 2 corresponding to the portion of sample 2 shown in FIG. 8F, in accordance with various aspects.

FIG. 9A illustrates a photograph of sample 1 after GLAD treatment with ˜75 nm Al, in accordance with various aspects.

FIG. 9B illustrates a photograph of sample 1 after GLAD treatment with ˜75 nm Al and after dry etching, in accordance with various aspects.

FIG. 9C illustrates a SEM image of sample 1 after GLAD treatment with ˜75 nm Al and after dry etching, in accordance with various aspects.

FIG. 9D illustrates sample 1 after GLAD treatment with ˜75 nm Al and after dry etching, in accordance with various aspects.

FIG. 10A illustrates a photograph of sample 1 after GLAD treatment, dry etching, and liftoff, in accordance with various aspects.

FIGS. 10B-C illustrate a SEM image of sample 1 from FIG. 10A, in accordance with various aspects.

FIG. 11 illustrates a method including (A) provide a grating, (B) perform GLAD on the grating to form caps, (C) directional dry etching of the capped grating, and (D) the result after dissolution of the photoresist, in accordance with various aspects.

### DETAILED DESCRIPTION OF THE INVENTION

Reference will now be made in detail to certain aspects of the disclosed subject matter. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in a specific order as recited herein. Alternatively, in any aspect(s) disclosed herein, specific acts may be carried out in any order without departing from the principles of the invention, except when a temporal or operational sequence is explicitly recited. Furthermore, specified acts can be carried out concurrently unless explicit claim language recites that they be carried out separately or the plain meaning of the claims would require it. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that about 0 wt % to about 5 wt % of the composition is the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

### Method of Forming a Nanopatterned Substrate.

Various aspects provide a method of forming a nanopatterned substrate. The method can include imprinting a deposited photoresist on a substrate with a stamp to form a nanopattern including nanofeatures on the substrate. The nanofeatures can include a gap therebetween. The method can include performing glancing angle deposition of a metal on the nanopattern to deposit the metal on the nanofeatures. The method can include directionally etching the nanopattern including the metal in a direction normal to a surface of the nanopattern to remove the photoresist in the gap between the nanofeatures and to expose the substrate in the gap between the nanofeatures. The method can include depositing a deposition material on the directionally etched nanopattern such that the deposition material is deposited on the exposed substrate in the gap between the nanofeatures and on the metal that is on the nanofeatures. The method can also include dissolving the deposited photoresist including the deposited deposition material thereon to remove the photoresist, the metal, and portions of the deposited deposition material that are on the photoresist from the substrate, to form the nanopatterned substrate including the deposition material deposited on the substrate in the gap between the nanofeatures.

The substrate can be any suitable substrate. The substrate can include a metal, metal oxide, polymer, silica, glass ceramic, ceramic, glass, or a combination thereof. The substrate can include a glass, such as a silicate glass, borosilicate glass, aluminosilicate glass, aluminoborosilicate glass, soda lime glass, Gorilla™ Glass (an alkali-metal alumino-silicate glass toughened by ion exchange of potassium for sodium), or a combination thereof.

In various aspects, the photoresist can be deposited on the substrate prior to the onset of the method. In other aspect, the method can include depositing the photoresist on the substrate, and can optionally include curing (e.g., UV-curing) and/or soft-baking the photoresist. The deposited photoresist can be a deposited photoresist that is cured and/or soft-baked. The photoresist can be a curable liquid photoresist, such as a UV-curable liquid photoresist.

The photoresist can be any suitable photoresist. The photoresist can include a photoresist that is thermally curable, a photoresist that is UV curable, a photoresist that is both UV- and thermally-curable, or a combination thereof. The photoresist can include a photoresist that is UV-curable. The photoresist can include MicroChemicals AZ P4000 series, MicroChemicals AZ 5200-E series, MicroChemicals AZ nLOF 2000 series, FujiFilm HiPR 6500 series, Megaposit SPR 220 series, Microposit S1800 series, Kayaku Su-8 2000 series, a thermal NIL resist (e.g., mr-I 9000M, mr-I 7000R, mr-I 8000R, mr-I TB 5, or mr-I PMMA), a UV curable NIL resist (e.g., mr-I NIL210, mr-UVCur21, mr-XNIL26, or mr-UVCur26SF, an NIL resist that is both UV- and thermally-curable (e.g., mr-NIL 6000E), or a combination thereof, wherein “mr” indicates Micro Resist Technology.

The nanopattern can be any suitable nanopattern that includes nanofeatures. The nanopattern can include a periodic pattern of the nanofeatures. The nanopattern can include a linear periodic grating. The grating can have a pitch (i.e., a distance between adjacent grooves) of 10 nm to 900 nm, or less than or equal to 900 nm and greater than or equal to 10 nm and less than, equal to, or greater than 20 nm, 30, 40, 50, 60, 70, 80, 90, 100, 120, 140, 160, 180, 200, 240, 260, 280, 300, 350, 400, 450, 500, 550, 600, 650, 700, 750, 800, or 850 nm. The nanofeatures can include any suitable nanofeatures, such as nanopores, nanopillars, nanowires, or a combination thereof. In various aspects, the nanopattern includes nanofeatures that are nanowires, wherein the nanowires are arranged in a pattern of a linear periodic grating on the substrate.

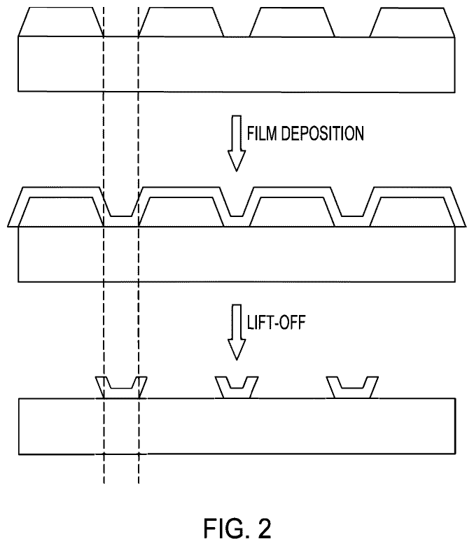

A nanofeature has at least one dimension small than 1 μm. The nanofeatures can have any suitable height. For example, the nanofeatures can have a height of 10 nm to 900 nm, or 50 nm to 500 nm, or less than or equal to 900 nm and greater than or equal to 10 nm and less than, equal to, or greater than 20 nm, 30, 40, 50, 60, 70, 80, 90, 100, 120, 140, 160, 180, 200, 240, 260, 280, 300, 350, 400, 450, 500, 550, 600, 650, 700, 750, 800, or 850 nm. The nanofeatures can have any suitable width. For example, the nanofeatures can have a width of 10 nm to 900 nm, or 50 nm to 500 nm, or less than or equal to 900 nm and greater than or equal to 10 nm and less than, equal to, or greater than 20 nm, 30, 40, 50, 60, 70, 80, 90, 100, 120, 140, 160, 180, 200, 240, 260, 280, 300, 350, 400, 450, 500, 550, 600, 650, 700, 750, 800, or 850 nm. The nanofeatures can have any suitable aspect ratio of nanofeature width to nanofeature height, such as 50:1 to 0.02:1, or 10:1 to 0.1:1, or less than or equal to 50:1 and greater than or equal to 0.02:1, 0.04:1, 0.06:1, 0.08:1, 0.1:1, 0.12:1, 0.14:1, 0.16:1, 0.18:1, 0.2:1, 0.25:1, 0.3:1, 0.35:1, 0.4:1, 0.45:1, 0.5:1, 0.55:1, 0.6:1, 0.65:1, 0.7:1, 0.75:1, 0.8:1, 0.85:1, 0.9:1, 0.95:1, 1:1, 1.05:1, 1.1:1, 1.2:1, 1.4:1, 1.6:1, 1.8:1, 2:1, 2.5:1, 3:1, 4:1, 5:1, 6:1, 8:1, 10:1, 12:1, 14:1, 16:1, 18:1, 20:1, 25:1, 30:1, 35:1, 40:1, or 45:1. The nanofeatures can include a gap therebetween having any suitable size, such as a size of 1 nm to 500 nm, or 20 nm to 300 nm, or less than or equal to 500 nm and greater than or equal to 1 nm and less than, equal to, or greater than 2 nm, 4, 6, 8, 10, 12, 14, 16, 18, 20, 25, 30, 40, 50, 60, 70, 80, 90, 100, 120, 140, 160, 180, 200, 220, 240, 260, 280, 300, 320, 340, 360, 380, 400, 420, 440, 460, or 480 nm. The gap between nanofeatures can be measured as the size of the exposed substrate between nanofeatures, such as the distance between the dotted lines shown in FIG. 2.

An exterior side of the nanofeatures can form any suitable angle with respect to the substrate, such as an angle of 45° to 90°, or 70° to 90°, or less than 90°, or less than or equal to 90 and greater than or equal to 45 and less than, equal to, or greater 46°, 48°, 50°, 52°, 54°, 56°, 58°, 60°, 62°, 64°, 66°, 68°, 70°, 71°, 72°, 73°, 74°, 75°, 76°, 77°, 78°, 79°, 80°, 81°, 82°, 83°, 84°, 85°, 86°, 87°, 88°, or 89°. The nanofeatures can have any suitable side profile, such as a trapezoidal side profile.

The method can include performing glancing angle deposition of a metal on the nanopattern to deposit the metal on the nanofeatures. The glancing angle deposition of the metal is a deposition that can be performed in one or more directions that are not orthogonal to a plane parallel to the substrate. The deposition can be any suitable deposition, such as chemical vapor deposition, physical vapor deposition, or a combination thereof. The glancing angle deposition of the metal can form caps on the nanofeatures, wherein the caps include the deposited metal. The glancing angle deposition can be performed in a single direction with respect to the substrate, or in multiple directions with respect to the substrate. For example, the glancing angle deposition of the metal can be performed at an angle of 1° to 60° with respect to a plane parallel to the substrate, or 5° to 30° with respect to a plane parallel to the substrate, or less than or equal to 60° and greater than or equal to 1° and less than, equal to, or greater than 1°, 2°, 3°, 4°, 5°, 6°, 7°8°, 9°, 10°, 11°, 12°, 13°, 14°, 15°, 16°, 17°, 18°, 19°, 20°, 21°, 22°, 23°, 24°, 25°, 26°, 27°, 28°, 29°, 30°, 32°, 34°, 36°, 38°, 40°, 42°, 44°, 46°, 48°, 50°, 52°, 54°, 56°, or 58°. The glancing angle deposition of the metal can be performed at an angle with respect to a plane parallel to the substrate such that substantially no metal is deposited in gaps between the nanofeatures. The glancing angle deposition of the metal can be performed while the substrate is rotating, and/or can be performed with rotation of the substrate between multiple sessions of the glancing angle deposition, in order to deposit metal from more than one direction with respect to the substrate.

Caps on the nanofeatures formed from the glancing angle deposition of the metal can include an overhang. The overhang can extend over a horizontal side of the nanofeatures (e.g., over an edge of a top side), can extend over exposed substrate in the gap, or a combination thereof. The overhang can extend over a horizontal side of the nanofeatures but not extend over exposed substrate in the gap. The overhang can extend over a horizontal side of the nanofeatures and also extend over exposed substrate in the gap.

The metal deposited by the glancing angle deposition of the metal can include any suitable metal. For example, the metal can include Al, Au, Ag, or a combination thereof. The metal can include Al. The glancing angle deposition of the metal can include depositing any suitable thickness of the metal (e.g., the cap can have any suitable thickness), such as a thickness of 5 nm to 500 nm, or 50 nm to 200 nm, or less than or equal to 500 nm and greater than or equal to 5 nm and less than, equal to, or greater than 6 nm, 8, 10, 12, 14, 16, 18, 20, 25, 30, 40, 50, 60, 70, 80, 90, 100, 120, 140, 160, 180, 200, 220, 240, 260, 280, 300, 320, 340, 360, 380, 400, 420, 440, 460, or 480 nm.

The method can include directionally etching the nanopattern including the metal in a direction normal to a surface of the nanopattern (e.g., a direction normal to a plane of the substrate) to remove the photoresist in the gap between the nanofeatures and to expose the substrate in the gap between the nanofeatures. The directional etching can include treatment of the nanopattern including the metal with plasma. The plasma can be any suitable plasma that can remove the photoresist in the gap between the nanofeatures, such as O₂/Ar plasma.

The method can include depositing a deposition material on the directionally etched nanopattern such that the deposition material is deposited on the exposed substrate in the gap between the nanofeatures and on the metal that is on the nanofeatures. The deposition of the deposition material can be performed in a direction normal to a surface of the nanopattern (e.g., a direction normal to a plane of the substrate). The deposition can be any suitable deposition, such as chemical vapor deposition, physical vapor deposition, or a combination thereof. The deposition material can be any suitable deposition material. The deposition material can include a metal, such as Al, Au, Ag, or a combination thereof. The deposition material can include Al.

The method can also include dissolving the deposited photoresist including the deposited deposition material thereon to remove the photoresist, the metal, and portions of the deposited deposition material that are on the photoresist from the substrate, to form the nanopatterned substrate including the deposition material deposited on the substrate in the gap between the nanofeatures. The dissolving can include contacting with a solution including any one or more suitable solvents that can dissolve the photoresist. The dissolving can include contacting with a solution including an organic solvent, an aqueous solvent, or a combination thereof. The dissolving can include contacting with a solution including pyrrolidinone, thiophene, a glycol-ether solvent, or a combination thereof. The dissolving can be performed for any suitable duration, such as a duration of 1 min to 96 h, or less than or equal to 96 h and greater than or equal to 1 min and less than, equal to, or greater than 2 min, 4, 6, 8, 10, 15, 20, 25, 30, 35, 40, 45, 50, 55 min, 1 h, 1.5, 2, 2.5, 3, 4, 5, 6, 8, 10, 12, 14, 16, 18, 20, 22, 24, 25, 30, 40, 50, 60, 70, 80, or 90 h. The dissolving can be performed at any suitable temperature, such as room temperature, or such as 0° C. to 100° C., or less than or equal to 100° C. and greater than or equal to 0° C. and less than, equal to, or greater than 5° C., 10, 15, 20, 25, 30, 35, 40, 45, 50, 55, 60, 65, 70, 75, 80, 85, 90, or 95° C. The dissolving can include agitation, such as stirring and/or ultrasonic agitation.

The deposition material that is deposited on the substrate in the gap between the nanofeatures on the nanopatterned substrate can have about the same width as the gap between the nanofeatures on the nanopatterned substrate (e.g., the same, with a difference in size of 0 nm, or larger or smaller by an amount that is less than 1 nm, 2, 4, 6, 8, 10, 12, 14, 16, 18, or less than 20 nm). The glancing angle deposition of the metal can form caps on the nanofeatures, the caps including an overhang, wherein the deposition material that is deposited on the substrate in the gap between the nanofeatures on the nanopatterned substrate can have about the same width as a distance between edges of the caps on the nanofeatures on either side of the gap (e.g., the same, with a difference in size of 0 nm, or larger or smaller by an amount that is less than 1 nm, 2, 4, 6, 8, 10, 12, 14, 16, 18, or less than 20 nm). The deposition material that is deposited on the substrate in the gap between the nanofeatures on the nanopatterned substrate can have a smaller width than the gap between the nanofeatures on the nanopatterned substrate (e.g., smaller by an amount that is less than 1 nm, 2, 4, 6, 8, 10, 12, 14, 16, 18, or less than 20 nm). The deposition material that is deposited on the substrate in the gap can have about the same height as height of the nanofeatures (e.g., the same, with a difference in size of 0 nm, or larger or smaller by an amount that is less than 1 nm, 2, 4, 6, 8, 10, 12, 14, 16, 18, or less than 20 nm). The deposition material that is deposited on the substrate in the gap can have a smaller height as compared to a height of the nanofeatures (e.g., smaller by an amount that is less than 1 nm, 2, 4, 6, 8, 10, 12, 14, 16, 18, or less than 20 nm).

The method can be a method of making any suitable device or apparatus. For example, the method can be a method of making a two-dimensional diffractive optic element (DOE), a metalens, a circular wire-grid polarizer, a linear wire-grid polarizer, or a combination thereof. The method can be a method of making a linear wire-grid polarizer. The method can be a method of making an LCD display.

In various aspects, the method includes performing a second glancing angle deposition on the nanopatterned substrate, to form a capped nanopatterned substrate. The second glancing angle deposition can be performed in any suitable way. The second glancing angle deposition of the metal is a deposition that can be performed in one or more directions that are not orthogonal to a plane parallel to the substrate. The deposition can be any suitable deposition, such as chemical vapor deposition, physical vapor deposition, or a combination thereof. The glancing angle deposition of the metal can form caps on the deposited nanofeatures on the substrate, wherein the caps include the deposited metal. The glancing angle deposition can be performed in a single direction with respect to the substrate, or in multiple directions with respect to the substrate. For example, the glancing angle deposition of the metal can be performed at an angle of 1° to 60° with respect to a plane parallel to the substrate, or 5° to 30° with respect to a plane parallel to the substrate, or less than or equal to 60° and greater than or equal to 10 and less than, equal to, or greater than 1°, 2°, 3°, 4°, 5°, 6°, 7°, 8°, 9°, 10°, 11°, 12°, 13°, 14°, 15°, 16°, 17°, 18°, 19°, 20°, 21°, 22°, 23°, 24°, 25°, 26°, 27°, 28°, 29°, 30°, 32°, 34°, 36°, 38°, 40°, 42°, 44°, 46°, 48°, 50°, 52°, 54°, 56°, or 58°. The angle of deposition can be sufficient to substantially avoid deposition in a gap between the deposited features (e.g., can avoid deposition on the substrate). The caps formed on the deposited features can include an overhang, such as an overhang at extends over at least a portion of a horizontal side of the deposited feature. The metal deposited in the second glancing angle deposition (e.g., the second metal) can be any suitable metal, such as Al, Au, Ag, or a combination thereof. The second glancing angle deposition of the metal can include depositing any suitable thickness of the metal (e.g., the cap can have any suitable thickness), such as a thickness of 5 nm to 500 nm, or 50 nm to 200 nm, or less than or equal to 500 nm and greater than or equal to 5 nm and less than, equal to, or greater than 6 nm, 8, 10, 12, 14, 16, 18, 20, 25, 30, 40, 50, 60, 70, 80, 90, 100, 120, 140, 160, 180, 200, 220, 240, 260, 280, 300, 320, 340, 360, 380, 400, 420, 440, 460, or 480 nm.

### Capped Nanopatterned Substrate.

In various aspects, the present invention provides a capped nanopatterned substrate. The capped nanopatterned substrate can be any suitable product formed by performing a second glancing angle deposition of a second metal onto the deposited material of the nanopatterned substrate formed by the method of forming a nanopatterned substrate described herein. For example, the capped nanopatterned substrate can include a substrate and a nanopattern including nanofeatures such as nanopores, nanopillars, nanowires, or a combination thereof. The nanofeatures contact the substrate and include a deposited material (e.g., the material that was deposited in the gap in the nanopattern). The capped nanopatterned substrate includes one or more caps on the nanofeatures. The caps are free of contact with the substrate. The caps include a deposited second metal (e.g., Al, Au, Ag, or a combination thereof), that was deposited via a second glancing angle deposition. The caps can include an overhang that extends at least partially over a horizontal side of the deposited nanofeatures, that extend at least partially over a gap between the deposited nanofeatures, or a combination thereof. The capped nanopatterned substrate can be a grating including lateral XY and/or XZ architecture (e.g., a “blazed” diffraction grating). The caps can be rim-like structures on the nanofeatures, such as rim-like structures on nanopores, nanopillars (e.g., nanopillars including peripheral rims), nanowires, or a combination thereof.

### EXAMPLES

Various aspects of the present invention can be better understood by reference to the following Examples which are offered by way of illustration. The present invention is not limited to the Examples given herein.

### Example 1. NIL+GLAD theory

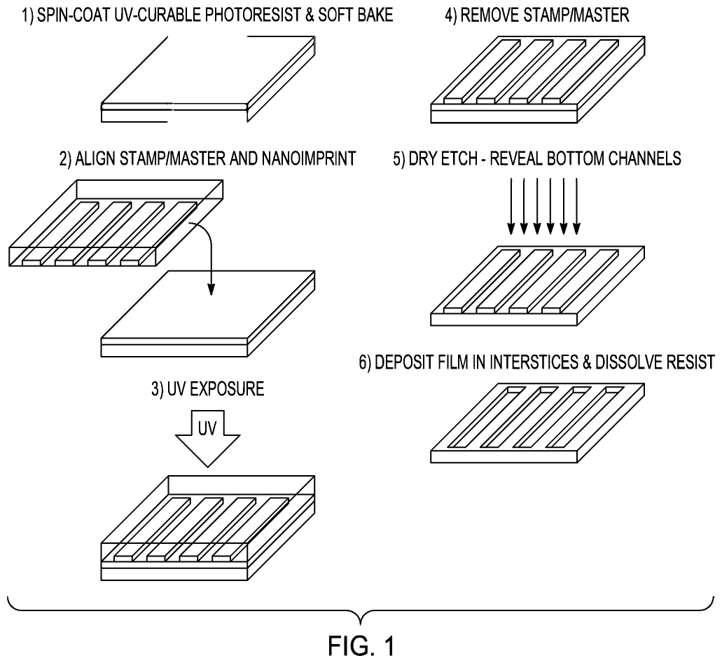

FIG. 1 illustrates a schematic showing a nanoimprint lithography (NIL) method. Various aspects of the present disclosure apply glancing angle metal deposition (GLAD) in certain steps of those identified in FIG. 1. Step 1 includes spin-coating, baking, and preparing the NIL photoresist (PR) for embossing step. Step 2 includes alignment of photoresist with master pattern and uniformly embossing. Step 3 includes exposure to UV light to cure the NIL photoresist, followed by baking to achieve a full cure. Step 4 includes detaching the master from the daughter without blemish, resulting in the daughter's uniform surface thickness and planarity. Step 5 includes RIE “dry” etching to etch the daughter's surface to expose the lower substrate simultaneously, thus retaining the nanofeatures and preparing the lower substrate to receive the deposited material. Step 6 includes chemical vapor deposition (CVD) or physical vapor deposition (PVD) of material into the narrow channels. “Lift-off” techniques are then applied for the removal of the excess deposited material and cured NIL photoresist.

FIG. 2 illustrates a schematic showing a nanoimprint photoresist “lift-off” that shows an issue with conventional techniques. FIG. 2 illustrates a schematic illustrating a nanoimprint after step 5 of FIG. 1 (top), showing the photoresist trapezoidal structure, which is a typical result, with film deposition (middle) showing an overall contiguous deposited layer, and lift-off (bottom) illustrating coarsening with dimensions greater than the original surface opening.

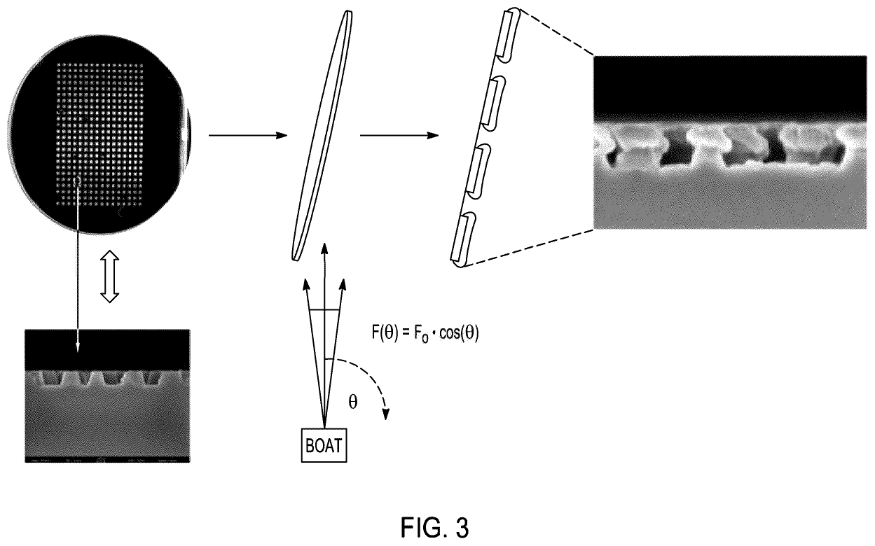

FIG. 3 illustrates a GLAD-imprint approach for higher resolution features. FIG. 3 illustrates a top view of a dewet sample (left top), a SEM image of the dewet sample illustrating the surface including randomly distributed circular nano-trapezoids (left bottom), a schematic illustrating glancing angle deposition (GLAD) (middle) (note that the sample platen can optionally rotate to provide homogeneous edge thickness on the deposited caps), and a SEM image illustrating the product of GLAD including caps on the trapezoidal features (right).

The GLAD parameters that can impact the metal-cap nanofeature topology can be both physical and chemical in nature. The final topology is very dependent on the physical angle θ between the sample platen and the evaporation boat (see, FIG. 3, middle), while the surface diffusion of the metal adatoms depends on the surface temperature and the energy of the metal atoms arriving at the sample's surface. The final topology is also dependent on the NIL photoresist surface energy, metal surface energy, and resulting mutual surface wetting. Circular rotation of the sample platen can be used ensure homogeneous edge thickness on nanofeatures; if used, the platen rotation rate can depend on the deposition rate, the total evaporation time, and the nanofeature edge thickness desired. These key parameters can be adjusted to optimize the final metal-cap nanofeature topology.

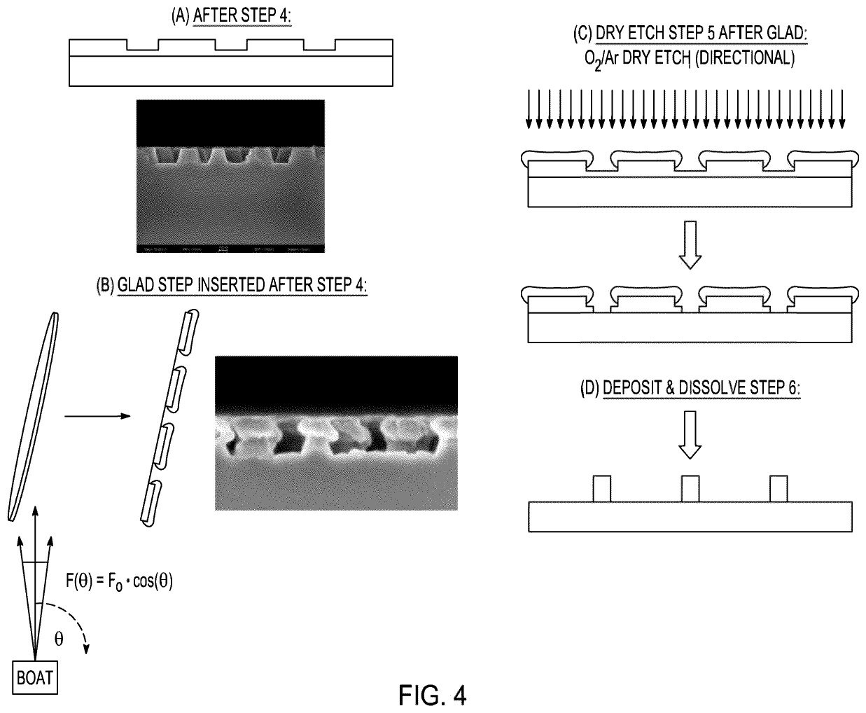

FIG. 4 illustrates a sequence of steps including GLAD that can increase the resolution of the NIL nanoimprint process shown in FIG. 1. FIG. 4 illustrates a sequence of steps including (A) providing an NIL nanofeature surface resulting from Step 4 of FIG. 1. Step (B) includes GLAD, which is applied directly to the NIL nanofeature surface using parameters that can be varied to achieve a desired metal “cap” structure that can serve as a subsequent etch mask. Step (C) illustrates directional dry etching, which can be performed with an O₂/Ar dry etch gas blend along the normal direction of the GLAD-coated surface to remove the underlying cured photoresist and expose a channel for subsequent deposition. Step (D) illustrates deposition and dissolution (lift-off). The lift-off can be greatly enhanced, resulting in clean walls without detachment issues.

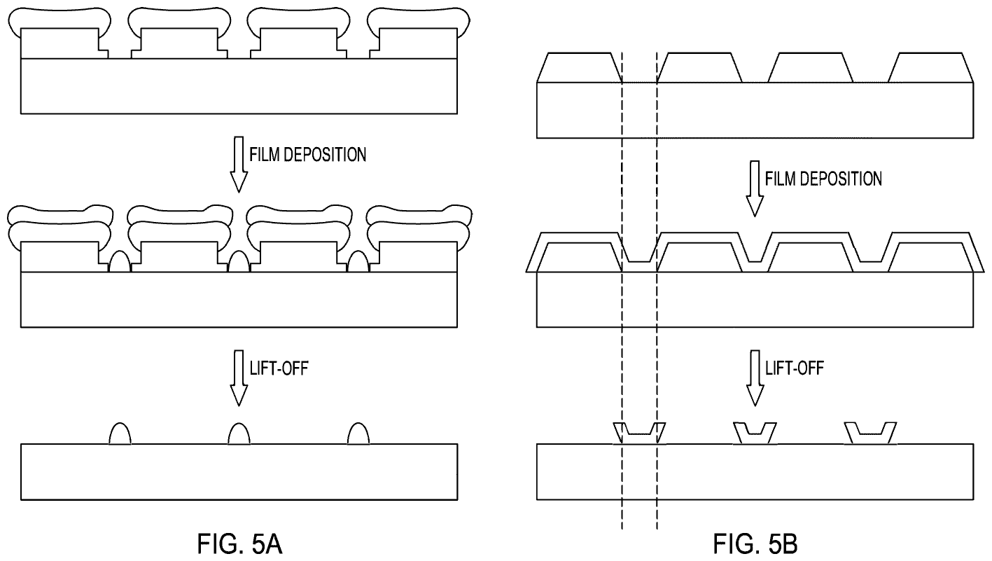

The addition of GLAD to NIL can result in the ability to close or “tune” gaps between nanofeatures besides enhancing lift-off. FIG. 5A illustrates a schematic showing a product of GLAD including caps (top), a product of film deposition thereon (middle), and a product formed after lift-off. In comparison, FIG. 5B illustrates a schematic illustrating a nanoimprint after step 5 of FIG. 1 (top), with film deposition (middle) and lift-off (bottom). A comparison between FIG. 5A (bottom) and FIG. 5B (bottom) illustrates that GLAD can allow production of features with a finer resolution (i.e., smaller features) and with a more highly controlled resolution (e.g., feature size is more precise) as compared to use of NIL alone. The size of the overhang of the caps produced during the GLAD can be used to control the size of inter-gap regions that receive the deposited firm.

### Example 2. NIL+GLAD Validation with Grating

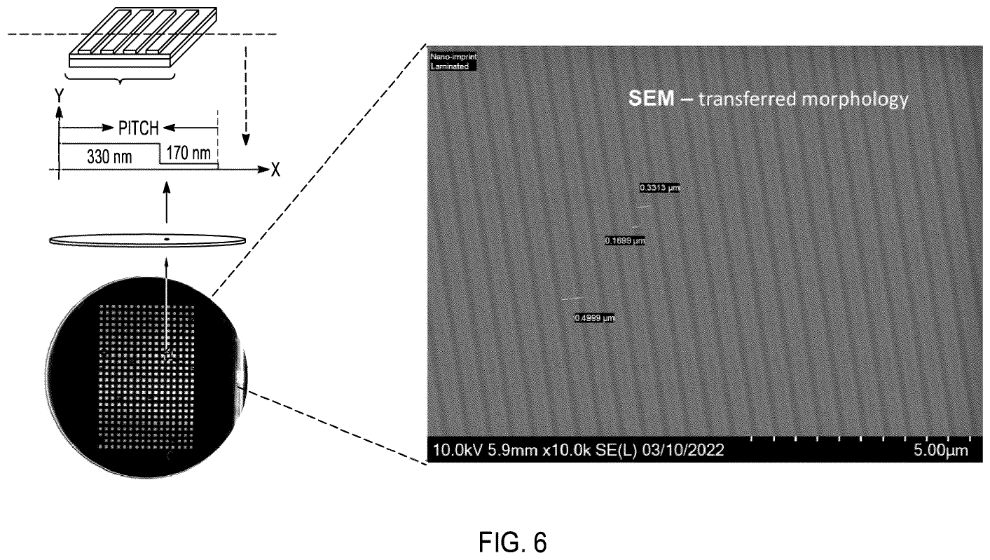

In this Example, the validity of the basic nanoimprint-GLAD approach is demonstrated. An EPIC grating sample was selected (a master having a 250 nm spacing, a 0.5 micron pitch, and 110 nm depth), after Step 4 of FIG. 1, as shown in FIG. 6. FIG. 6 illustrates a grating daughter formed after step 4 of FIG. 1, including dimensions (top left), side illustration (middle left), photograph from top (bottom left), and a SEM image thereof (right). The sample had a diameter of 6″. The sample had a ˜499 nm grating pitch with 170 nm wide channels. The photoresist used was MicroResist UV-NIL26.

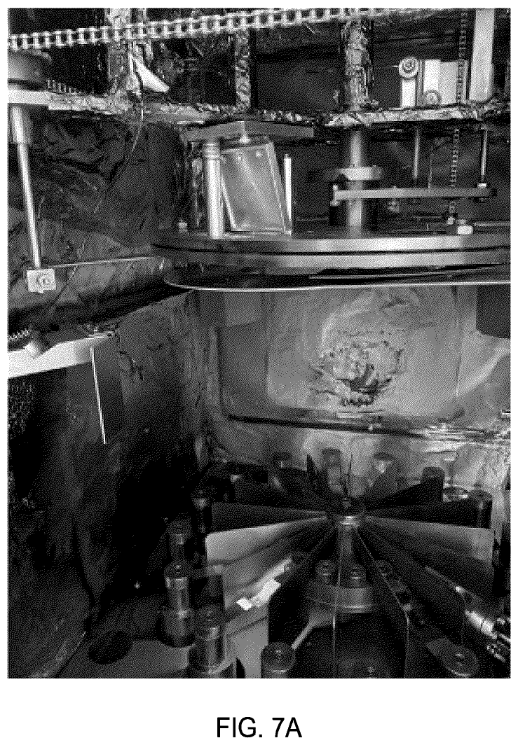

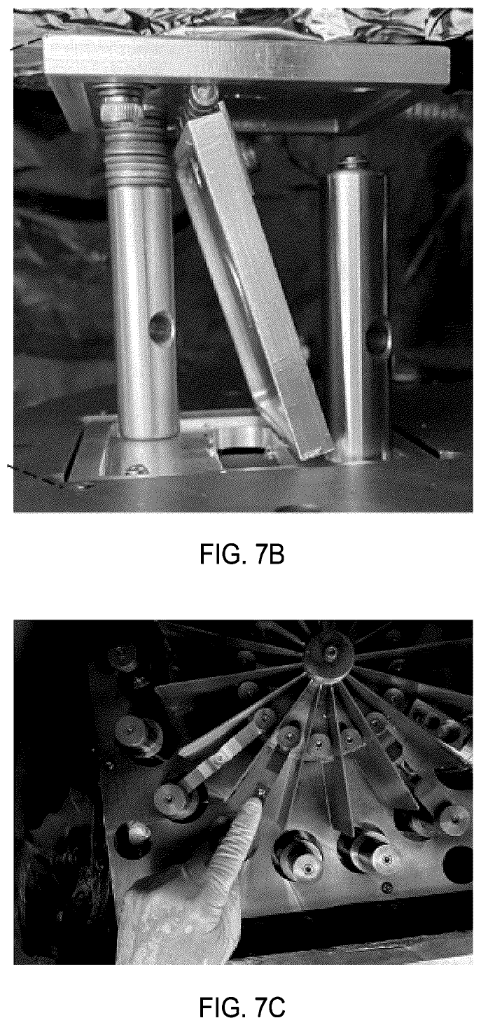

The sample was then placed in the GLAD evaporation chamber as shown in FIGS. 7A-C. FIG. 7A illustrates a photograph of the GLAD apparatus. The evaporation chamber was operated at ˜1×10⁻⁶ Torr with an alumina-coated tungsten boat at the base of the chamber for aluminum deposition with the GLAD fixture positioned on the platen toward the top of the image at the top of the image beneath the rotating chain link. FIG. 7B illustrates a photograph of the chamber of the GLAD apparatus from FIG. 7A, which contains the GLAD fixture. The GLAD deposition angle θ was 17°. The sample was taped directly to its center with AL deposited through the slot aperture at the base of FIG. 7B. FIG. 7C illustrates a photograph showing a top-view of the GLAD apparatus shown in FIG. 7A, shown from a height of ˜18″, with the finger in the image pointing at the AL source.

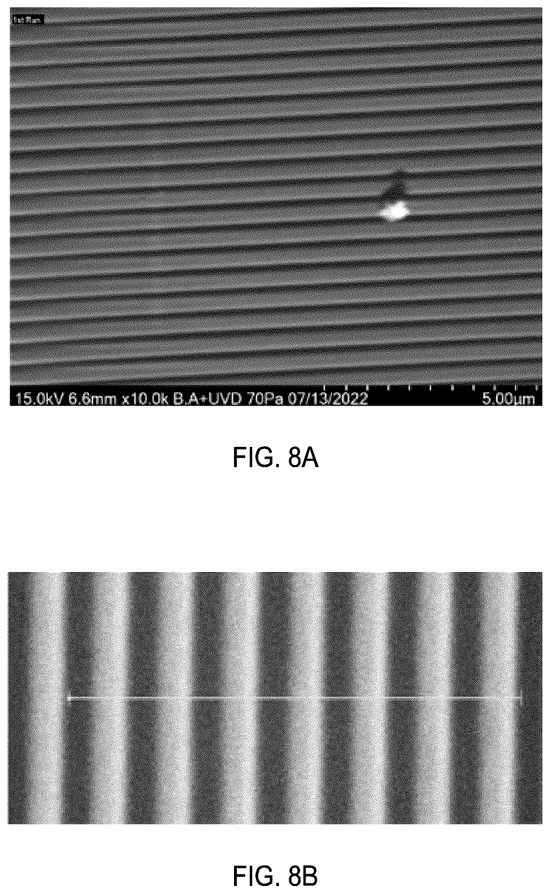

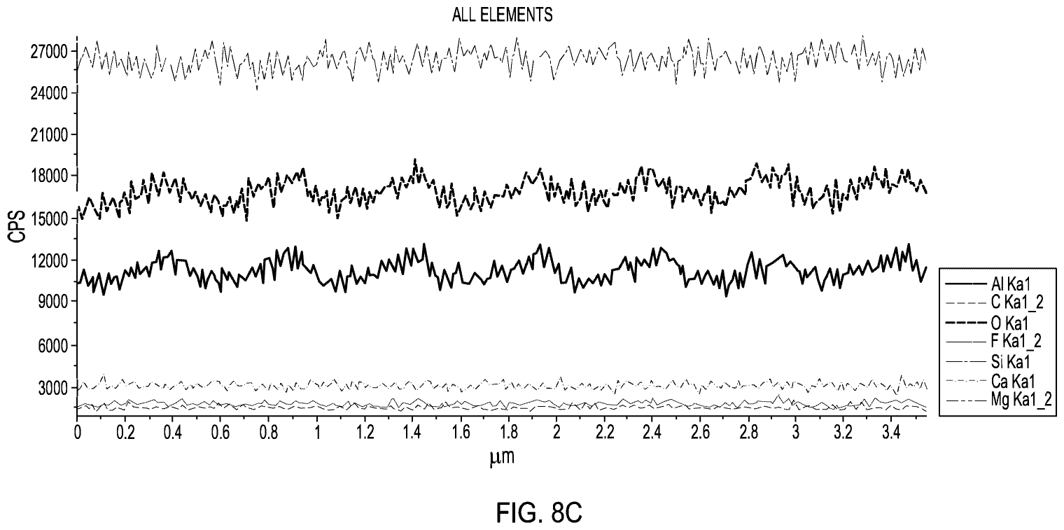

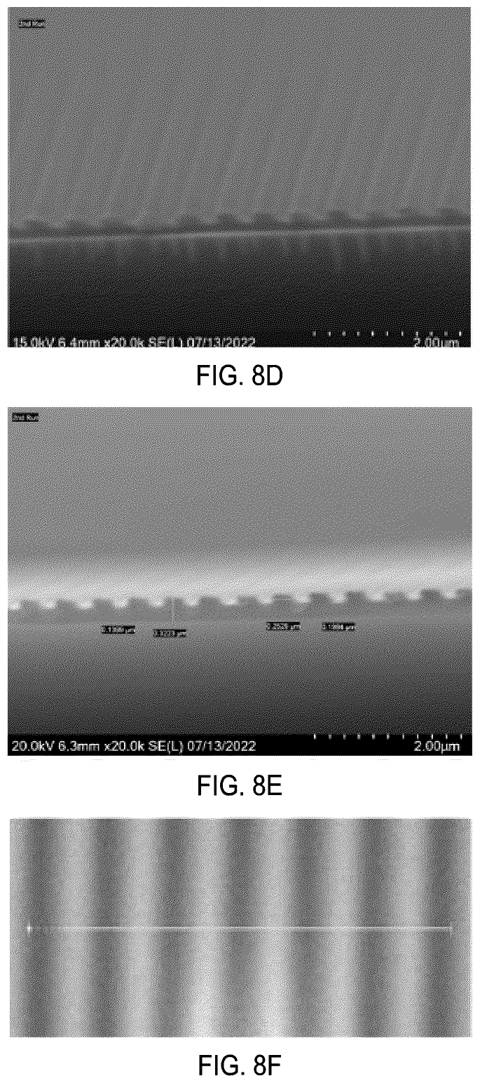

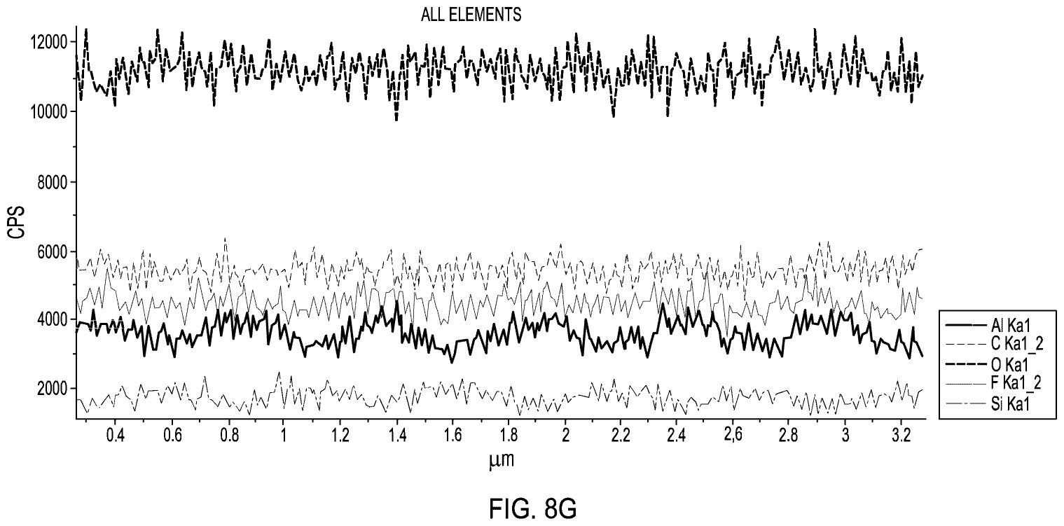

Two samples were run in the GLAD setup. The first had 75 nm Al deposited on its surface through the aperture of the GLAD apparatus. The GLAD deposition angle θ=17° was used to ensure the channel bottoms would not be coated. No effort was made to flip the sample and perform a second deposition in the opposite direction, to prepare symmetric-structure deposition samples. Thus, both GLAD samples 1 and 2 were asymmetric. This asymmetry may be observed in FIGS. 8A-G. FIG. 8A illustrates a SEM image of sample 1 after GLAD deposition with ˜75 nm Al. FIG. 8B illustrates a SEM image of sample 1 after GLAD deposition with a line indicating the source of EDX scan data in FIG. 8C. FIG. 8C illustrates an EDX scan of sample 1 corresponding to the portion of sample 1 shown in FIG. 8B. FIGS. 8D-8E illustrate SEM images of sample 2 after GLAD deposition with ˜150 nm Al. FIG. 8F illustrates a SEM image of sample 2 after GLAD deposition with a line indicating the source of EDX scan data in FIG. 8G. FIG. 8G illustrates an EDX scan of sample 2 corresponding to the portion of sample 2 shown in FIG. 8F.

A faint peak asymmetry in GLAD sample 1 might be observed in the Al and oxygen EDX traces (FIGS. 8B-C) reflecting the approach and direction of the evaporating Al elements and its adatom assembly. GLAD sample 2 might provide a more visual validation of this asymmetry by close examination of the two SEM images shown in FIGS. 8D-E. The lower magnification SEM image in FIG. 8D also shows another attribute peculiar to these experimental samples: their photoresist was not fully cured. They appear as tiny threadlike features along the bottom edge where the sample was scored and broken during the SEM sample preparation procedure. While we have since corrected this feature, we nonetheless continued with these samples for our GLAD validation experiments.

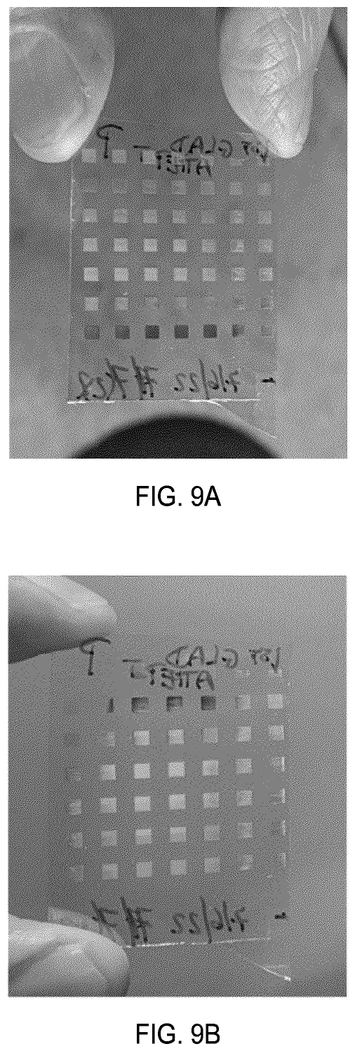

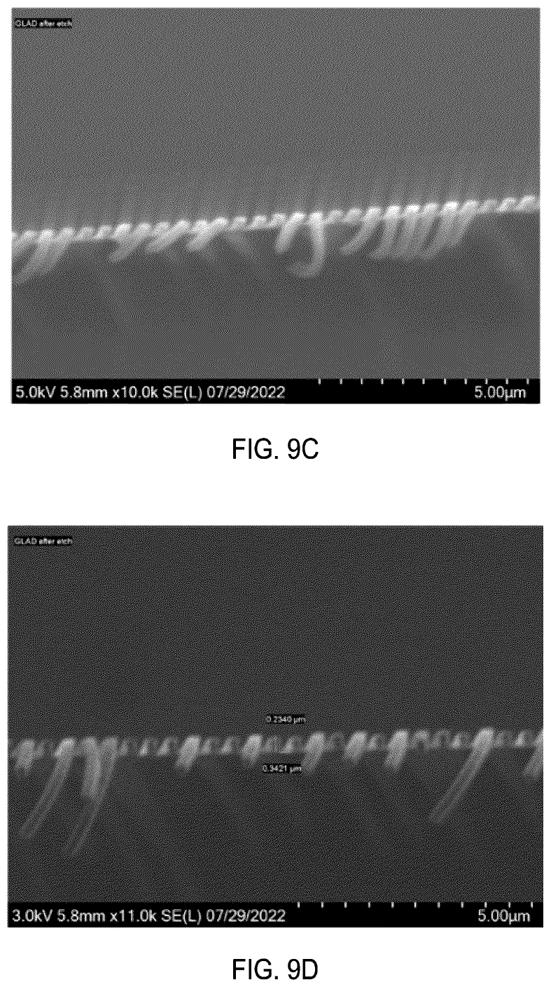

GLAD sample 1 was then subjected to an RIE dry etch. FIG. 9A illustrates a photograph of sample 1 after GLAD treatment with ˜75 nm Al. FIG. 9B illustrates a photograph of sample 1 after GLAD treatment with ˜75 nm Al and after dry etching. FIG. 9C illustrates a SEM image of sample 1 after GLAD treatment with ˜75 nm Al and after dry etching. FIG. 9D illustrates sample 1 after GLAD treatment with ˜75 nm Al and after dry etching. The dry etching was a directional etch performed from the direction normal to the pattern surface. The dry etching was performed with the parameters of 250 W RF forward power (straight walls), 100 W ICP forward power (ion density), 45 scmm O₂, 5 sccm Ar, chamber pressure=2 mTorr, with ˜100 nm photoresist completely removed in 2 minutes. Stringy features in FIGS. 9C-D are due to incomplete curing of photoresist.

A slight asymmetry to the grating surface pattern in the SEM images correlates with the 17° GLAD deposition angle used. Again, the threadlike features along the bottom edge are clearly observed where the sample was scored and broken during the SEM sample preparation procedure. Still, it appears the GLAD with oxidizing dry etch protocol did indeed provide a mask-like opening through which a normal Al evaporation would result in a direct glass substrate metal pattern coating.

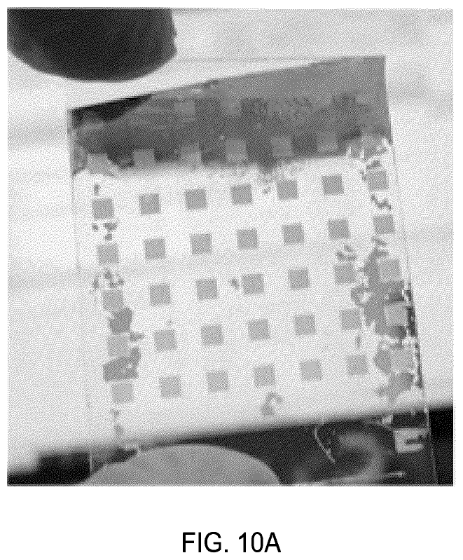

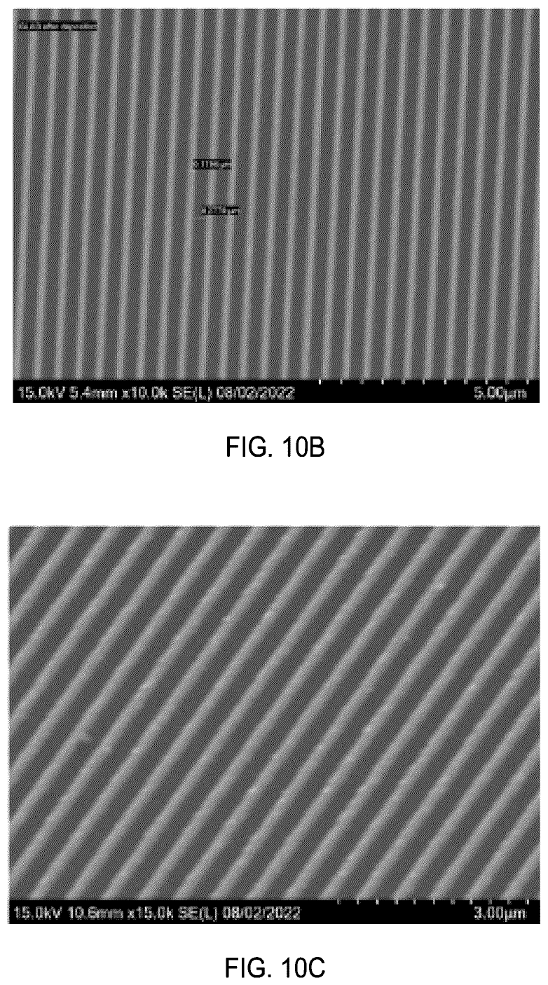

An additional oxygen plasma cleaning step (an isotropic oxygen plasma cleaning step for ˜3 minutes) was applied to the dry-etched GLAD sample 1 to ensure a clean surface, with clear channel bottom exposure, was indeed attained, prior to the final deposition step. It was then placed on a platen facing directly downward at the Al evaporation source for a 137 nm Al deposition run. The liftoff was relatively straightforward with a simple ultrasonication in a pyrrolidinone, thiophene, and glycol-ether solvent mixture (Baker® PRS-2000). A partial liftoff occurred after a brief 15-minute exposure to the ultrasonicating bath, but the sample was soaked in photoresist stripper to complete the liftoff. FIG. 10A illustrates a photograph of sample 1 after GLAD treatment, dry etching, and liftoff. FIGS. 10B-C illustrate a SEM image of sample 1 from FIG. 10A, with 10B being a lower resolution image, and with 10C being a higher resolution image showing GLAD sample 1 grating dimensions. To our knowledge, the resulting structure is the first nano-patterned structure using this nanoimprint-GLAD methodology, providing prospects for scaling, low-cost fabrication, and high nano-scale device performance.

### Example 3. Wire-Grid Polarizer (Hypothetical)

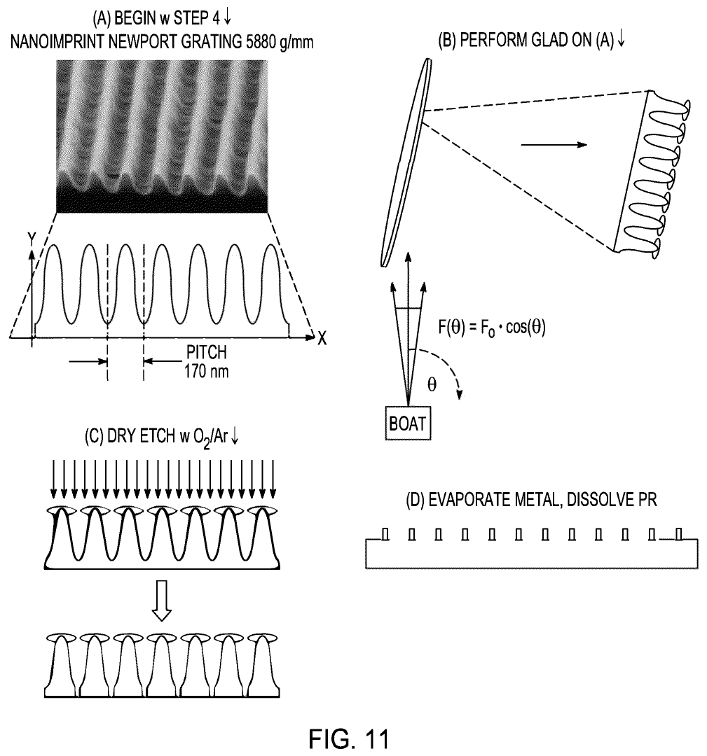

This Example describes a hypothetical aspect illustrating an approach to fabricating a wire-grid polarizer using the NIL/GLAD protocol. The process, as illustrated in FIG. 11, begins with making a nickel master of Newport ruled grating (Part #—33066FL01-290R) with 5880 grooves per grating, as shown in FIG. 11 Step (A). Step B includes performing GLAD on the grating daughter to form caps. Step C includes performing directional dry etching of the capped grating. Step D includes dissolution of the photoresist and lift-off, giving a grating structure with a 170 nm pitch and 85 nm Al line traces.

The performance of the grating structure maybe interpreted with the aid of an analytical calculation. This analysis relies on analytic formula derived from application of Maxwell equations to the arrival of plane waves incident on a metallic wire grid (J. P. Auton, Applied Optics, June 1967, Vol. 6 (No. 6), pp. 1023-1027, (“Auton”)). While the theory is derived in a manner utilizing equivalent circuits, the rigorous application of the formula is directly applicable to the present grating structures.

One of our aims is to fabricate a wire-grid grating structure having 170 nm pitch and 85 nm Al lines in a linear array. Using a design wavelength of 405 nm as the typical pump wavelength from either a mini or micro-LED array, the resulting λ/d=4.8 value metric indicates that equations 5 and 6 from Auton are predictive to within 1% of a full numerical analysis. The transmission of perpendicular polarization is greater than 90% with the parallel polarization suppressed to nearly 0% transmission. The overall degree of polarization P, or extinction ratio, is predicted to be greater than 140, supporting the notion that such a nano-patterned wire-grid polarizer is indeed suitable for resuscitating LCD glass usage because of its superior polarization-ensuring capability, fabricated at low cost.

The terms and expressions that have been employed are used as terms of description and not of limitation, and there is no intention in the use of such terms and expressions of excluding any equivalents of the features shown and described or portions thereof, but it is recognized that various modifications are possible within the scope of the aspects of the present invention. Thus, it should be understood that although the present invention has been specifically disclosed by specific aspects and optional features, modification and variation of the concepts herein disclosed may be resorted to by those of ordinary skill in the art, and that such modifications and variations are considered to be within the scope of aspects of the present invention.

### Exemplary Aspects

The following exemplary aspects are provided, the numbering of which is not to be construed as designating levels of importance:

Aspect 1 provides a method of forming a nanopatterned substrate, the method comprising:
imprinting a deposited photoresist on a substrate with a stamp to form a nanopattern comprising nanofeatures on the substrate, the nanofeatures comprising a gap therebetween; performing glancing angle deposition of a metal on the nanopattern to deposit the metal on the nanofeatures;
directionally etching the nanopattern including the metal in a direction normal to a surface of the nanopattern to remove the photoresist in the gap between the nanofeatures and to expose the substrate in the gap between the nanofeatures;
depositing a deposition material on the directionally etched nanopattern such that the deposition material is deposited on the exposed substrate in the gap between the nanofeatures and on the metal that is on the nanofeatures; and
dissolving the deposited photoresist comprising the deposited deposition material thereon to remove the photoresist, the metal, and portions of the deposited deposition material that are on the photoresist from the substrate, to form the nanopatterned substrate comprising the deposition material that was deposited on the substrate in the gap between the nanofeatures.

Aspect 2 provides the method of Aspect 1, wherein the substrate comprises a metal, metal oxide, polymer, silica, glass ceramic, ceramic, glass, or a combination thereof.

Aspect 3 provides the method of any one of Aspects 1-2, wherein the substrate comprises a silicate glass, borosilicate glass, aluminosilicate glass, aluminoborosilicate glass, soda lime glass, Gorilla™ Glass (an alkali-metal alumino-silicate glass toughened by ion exchange of potassium for sodium), or a combination thereof.

Aspect 4 provides the method of any one of Aspects 1-3, further comprising depositing the photoresist on the substrate.

Aspect 5 provides the method of any one of Aspects 1-4, wherein the deposited photoresist is a deposited and cured photoresist.

Aspect 6 provides the method of any one of Aspects 1-5, wherein the deposited photoresist is a deposited and soft-baked photoresist.

Aspect 7 provides the method of any one of Aspects 1-6, wherein the photoresist comprises a UV-curable liquid photoresist.

Aspect 8 provides the method of any one of Aspects 1-7, wherein the photoresist comprises a photoresist that is thermally curable, a photoresist that is UV curable, a photoresist that is both UV- and thermally-curable, or a combination thereof.

Aspect 9 provides the method of any one of Aspects 1-8, wherein the photoresist comprises a photoresist that is UV-curable.

Aspect 10 provides the method of any one of Aspects 1-9, wherein the nanopattern comprises a periodic pattern of the nanofeatures.

Aspect 11 provides the method of any one of Aspects 1-10, wherein the nanopattern comprises a linear periodic grating.

Aspect 12 provides the method of Aspect 11, wherein the grating has a pitch of 10 nm to 900 nm.

Aspect 13 provides the method of any one of Aspects 1-12, wherein the nanofeatures comprise nanopores, nanopillars, nanowires, or a combination thereof.

Aspect 14 provides the method of any one of Aspects 1-13, wherein the nanofeatures comprise nanowires arranged in a pattern of a linear periodic grating.

Aspect 15 provides the method of any one of Aspects 1-14, wherein the nanofeatures have a height of 10 nm to 900 nm.

Aspect 16 provides the method of any one of Aspects 1-15, wherein the nanofeatures have a height of 50 nm to 500 nm.

Aspect 17 provides the method of any one of Aspects 1-16, wherein the nanofeatures have a width of 10 nm to 900 nm.

Aspect 18 provides the method of any one of Aspects 1-17, wherein the nanofeatures have a width of 50 nm to 500 nm.

Aspect 19 provides the method of any one of Aspects 1-18, wherein the nanofeatures have an aspect ratio of width to height of 50:1 to 0.02:1.

Aspect 20 provides the method of any one of Aspects 1-19, wherein the nanofeatures have an aspect ratio of width to height of 10:1 to 1:10.

Aspect 21 provides the method of any one of Aspects 1-20, wherein the nanofeatures comprise a gap therebetween, wherein the gap is 1 nm to 500 nm.

Aspect 22 provides the method of Aspect 21, wherein the gap is 20 nm to 300 nm.

Aspect 23 provides the method of any one of Aspects 1-22, wherein an exterior side of the nanofeatures form an angle with respect to the substrate of 450 to 90°.

Aspect 24 provides the method of any one of Aspects 1-23, wherein an exterior side of the nanofeatures form an angle with respect to the substrate of 70° to 90°.

Aspect 25 provides the method of any one of Aspects 1-24, wherein an exterior side of the nanofeatures form an angle with respect to the substrate of less than 90°.

Aspect 26 provides the method of Aspect 25, wherein the nanofeatures comprise a trapezoidal side profile.

Aspect 27 provides the method of any one of Aspects 1-26, wherein the glancing angle deposition of the metal is performed at an angle of 1° to 60° with respect to a plane parallel to the substrate.

Aspect 28 provides the method of any one of Aspects 1-27, wherein the glancing angle deposition of the metal is performed at an angle of 5° to 30° with respect to a plane parallel to the substrate.

Aspect 29 provides the method of any one of Aspects 1-28, wherein the glancing angle deposition of the metal is performed at an angle with respect to a plane parallel to the substrate such that substantially no metal is deposited in gaps between the nanofeatures.

Aspect 30 provides the method of any one of Aspects 1-29, wherein the glancing angle deposition of the metal is performed in a single direction with respect to the substrate.

Aspect 31 provides the method of any one of Aspects 1-30, wherein the glancing angle deposition of the metal is performed in multiple directions with respect to the substrate.

Aspect 32 provides the method of any one of Aspects 1-31, wherein the glancing angle deposition of the metal is performed while the substrate is rotating or is performed with rotation of the substrate between multiple sessions of the glancing angle deposition.

Aspect 33 provides the method of any one of Aspects 1-32, wherein the glancing angle deposition of the metal forms caps on the nanofeatures, the caps comprising an overhang.

Aspect 34 provides the method of Aspect 33, wherein the overhang extends over a horizontal side of the nanofeatures, extends over exposed substrate in the gap, or a combination thereof.

Aspect 35 provides the method of any one of Aspects 33-34, wherein the overhang extends over the horizontal side of the nanofeatures but does not extend over exposed substrate in the gap.

Aspect 36 provides the method of any one of Aspects 33-35, wherein the overhang extends over the horizontal side of the nanofeatures and extends over exposed substrate in the gap.

Aspect 37 provides the method of any one of Aspects 1-36, wherein the metal comprises Al, Au, Ag, or a combination thereof.

Aspect 38 provides the method of any one of Aspects 1-37, wherein the metal comprises Al.

Aspect 39 provides the method of any one of Aspects 1-38, wherein the glancing angle deposition of the metal comprises deposition of a thickness of the metal of 5 nm to 500 nm.

Aspect 40 provides the method of any one of Aspects 1-39, wherein the glancing angle deposition of the metal comprises deposition of a thickness of the metal of 50 nm to 200 nm.

Aspect 41 provides the method of any one of Aspects 1-40, wherein the directional etching comprises treatment with plasma.

Aspect 42 provides the method of any one of Aspects 1-41, wherein the directional etching comprises treatment with O₂/Ar plasma.

Aspect 43 provides the method of any one of Aspects 1-42, wherein the deposition comprises chemical vapor deposition, physical vapor deposition, or a combination thereof.

Aspect 44 provides the method of any one of Aspects 1-43, wherein the deposition material comprises Al, Au, Ag, or a combination thereof.

Aspect 45 provides the method of any one of Aspects 1-44, wherein the deposition material comprises Al.

Aspect 46 provides the method of any one of Aspects 1-45, wherein the dissolving comprises contacting with a solution comprising an organic solvent, an aqueous solvent, or a combination thereof.

Aspect 47 provides the method of any one of Aspects 1-46, wherein the dissolving comprises contacting with a solution comprising pyrrolidinone, thiophene, a glycol-ether solvent, or a combination thereof.

Aspect 48 provides the method of any one of Aspects 1-47, wherein the dissolving comprises dissolving for a duration of 1 min to 96 h.

Aspect 49 provides the method of any one of Aspects 1-48, wherein the deposition material that is deposited on the substrate in the gap between the nanofeatures on the nanopatterned substrate has about the same width as the gap between the nanofeatures on the nanopatterned substrate.

Aspect 50 provides the method of any one of Aspects 1-49, wherein the glancing angle deposition of the metal forms caps on the nanofeatures, the caps comprising an overhang, wherein the deposition material that is deposited on the substrate in the gap between the nanofeatures on the nanopatterned substrate has about the same width as a distance between edges of the caps on the nanofeatures on either side of the gap.

Aspect 51 provides the method of any one of Aspects 1-50, wherein the deposition material that is deposited on the substrate in the gap between the nanofeatures on the nanopatterned substrate has a smaller width than the gap between the nanofeatures on the nanopatterned substrate.

Aspect 52 provides the method of any one of Aspects 1-51, wherein the deposition material that is deposited on the substrate in the gap has about the same height as a height of the nanofeatures.

Aspect 53 provides the method of any one of Aspects 1-52, wherein the deposition material that is deposited on the substrate in the gap has a smaller height as compared to a height of the nanofeatures.

Aspect 54 provides the method of any one of Aspects 1-53, wherein the nanopatterned surface comprises a linear periodic grating.

Aspect 55 provides the method of Aspect 54, wherein the grating has a pitch of 10 nm to 900 nm.

Aspect 56 provides the method of any one of Aspects 1-55, wherein the method is a method of making a two-dimensional diffractive optic element (DOE), a metalens, a circular wire-grid polarizer, a linear wire-grid polarizer, or a combination thereof.

Aspect 57 provides the method of any one of Aspects 1-56, wherein the method is a method of making a linear wire-grid polarizer.

Aspect 58 provides the method of any one of Aspects 1-57, wherein the method is a method of making an LCD display.

Aspect 59 provides the method of any one of Aspects 1-58, wherein the method is a method of forming a capped nanopatterned substrate, wherein the method further comprises performing glancing angle deposition of a metal on the on the deposition material of the nanopatterned substrate that was deposited on the substrate in the gap between the nanofeatures, to form the capped nanopatterned substrate.

Aspect 60 provides a method of making a linear wire-grid polarizer, the method comprising:
imprinting a deposited photoresist on a substrate with a stamp to form a nanopattern comprising nanofeatures on the substrate, the nanofeatures comprising a gap therebetween;
performing glancing angle deposition of a metal comprising Al on the nanopattern to deposit the metal on the nanofeatures;
directionally etching the nanopattern including the metal in a direction normal to a surface of the nanopattern to remove the photoresist in the gap between the nanofeatures and to expose the substrate in the gap between the nanofeatures;
depositing a deposition material comprising Al on the directionally etched nanopattern such that the deposition material is deposited on the exposed substrate in the gap between the nanofeatures and on the metal that is on the nanofeatures; and
dissolving the deposited photoresist comprising the deposited deposition material thereon to remove the photoresist, the metal, and portions of the deposited deposition material that are on the photoresist from the substrate, to form the linear wire-grid polarizer comprising the deposition material deposited on the substrate in the gap between the nanofeatures;
wherein the deposition material deposited on the substrate in the gap between the nanofeatures has a pitch of 160 nm to 180 nm and a width of 80 nm to 90 nm.

Aspect 61 provides a capped nanopatterned substrate formed by the method of Aspect 59.

Aspect 62 provides a capped nanopatterned substrate comprising:
a substrate;
a nanopattern comprising nanofeatures comprising nanopores, nanopillars, nanowires, or a combination thereof, wherein the nanofeatures contact the substrate and comprise a deposition material; and
one or more caps on the nanofeatures, wherein the caps are free of contact with the substrate, wherein the caps comprise a deposited metal.

Aspect 62 provides the method of any one or any combination of Aspects 1-61 optionally configured such that all elements or options recited are available to use or select from.

What is claimed is:

1. A method of forming a nanopatterned substrate, the method comprising:
imprinting a deposited photoresist on a substrate with a stamp to form a nanopattern comprising nanofeatures on the substrate, the nanofeatures comprising a gap therebetween;
performing glancing angle deposition of a metal on the nanopattern to deposit the metal on the nanofeatures;
directionally etching the nanopattern including the metal in a direction normal to a surface of the nanopattern to remove the photoresist in the gap between the nanofeatures and to expose the substrate in the gap between the nanofeatures;
depositing a deposition material on the directionally etched nanopattern such that the deposition material is deposited on the exposed substrate in the gap between the nanofeatures and on the metal that is on the nanofeatures; and
dissolving the deposited photoresist comprising the deposited deposition material thereon to remove the photoresist, the metal, and portions of the deposited deposition material that are on the photoresist from the substrate, to form the nanopatterned substrate comprising the deposition material deposited on the substrate in the gap between the nanofeatures.

2. The method of claim 1, wherein the substrate comprises a metal, metal oxide, polymer, silica, glass ceramic, ceramic, glass, or a combination thereof.

3. The method of claim 1, wherein the nanopattern comprises a periodic pattern of the nanofeatures.

4. The method of claim 1, wherein the nanofeatures comprise nanopores, nanopillars, nanowires, or a combination thereof.

5. The method of claim 1, wherein the nanofeatures comprise nanowires arranged in a pattern of a linear periodic grating, wherein the grating has a pitch of 10 nm to 900 nm.

6. The method of claim 1, wherein the nanofeatures have a height of 10 nm to 900 nm and a width of 10 nm to 900 nm, and wherein the nanofeatures have an aspect ratio of width to height of 50:1 to 0.02:1.

7. The method of claim 1, wherein the gap is 1 nm to 500 nm.

8. The method of claim 1, wherein an exterior side of the nanofeatures form an angle with respect to the substrate of 45° to 90°.

9. The method of claim 1, wherein the glancing angle deposition of the metal is performed at an angle of 1° to 60° with respect to a plane parallel to the substrate.

10. The method of claim 1, wherein the glancing angle deposition of the metal forms caps on the nanofeatures, the caps comprising an overhang, wherein the overhang extends over a horizontal side of the nanofeatures, extends over exposed substrate in the gap, or a combination thereof.

11. The method of claim 1, wherein the metal comprises Al, Au, Ag, or a combination thereof.

12. The method of claim 1, wherein the glancing angle deposition of the metal comprises deposition of a thickness of the metal of 5 nm to 500 nm.

13. The method of claim 1, wherein the deposition material comprises Al, Au, Ag, or a combination thereof.

14. The method of claim 1, wherein the dissolving comprises contacting with a solution comprising an organic solvent, an aqueous solvent, or a combination thereof.

15. The method of claim 1, wherein the deposition material that is deposited on the substrate in the gap between the nanofeatures on the nanopatterned substrate has about the same width as the gap between the nanofeatures on the nanopatterned substrate.

16. The method of claim 1, wherein the glancing angle deposition of the metal forms caps on the nanofeatures, the caps comprising an overhang, wherein the deposition material that is deposited on the substrate in the gap between the nanofeatures on the nanopatterned substrate has about the same width as a distance between edges of the caps on the nanofeatures on either side of the gap.

17. The method of claim 1, wherein the method is a method of making a two-dimensional diffractive optic element (DOE), a metalens, a circular wire-grid polarizer, a linear wire-grid polarizer, an LCD display, or a combination thereof.

18. The method of claim 1, wherein the method is a method of forming a capped nanopatterned substrate, wherein the method further comprises performing glancing angle deposition of a second metal on the on the deposition material of the nanopatterned substrate that was deposited on the substrate in the gap between the nanofeatures, to form the capped nanopatterned substrate.

19. A method of making a linear wire-grid polarizer, the method comprising:
imprinting a deposited photoresist on a substrate with a stamp to form a nanopattern comprising nanofeatures on the substrate, the nanofeatures comprising a gap therebetween;
performing glancing angle deposition of a metal comprising Al on the nanopattern to deposit the metal on the nanofeatures;
directionally etching the nanopattern including the metal in a direction normal to a surface of the nanopattern to remove the photoresist in the gap between the nanofeatures and to expose the substrate in the gap between the nanofeatures;
depositing a deposition material comprising Al on the directionally etched nanopattern such that the deposition material is deposited on the exposed substrate in the gap between the nanofeatures and on the metal that is on the nanofeatures; and
dissolving the deposited photoresist comprising the deposited deposition material thereon to remove the photoresist, the metal, and portions of the deposited deposition material that are on the photoresist from the substrate, to form the linear wire-grid polarizer comprising the deposition material deposited on the substrate in the gap between the nanofeatures;
wherein the deposition material deposited on the substrate in the gap between the nanofeatures has a pitch of 160 nm to 180 nm and a width of 80 nm to 90 nm.

20. A capped nanopatterned substrate comprising:
a substrate;
a nanopattern comprising nanofeatures comprising nanopores, nanopillars, nanowires, or a combination thereof, wherein the nanofeatures contact the substrate and comprise a deposited metal; and
one or more caps on the nanofeatures, wherein the caps are free of contact with the substrate, wherein the caps comprise a deposited second metal.
